(19) United States
(12) Patent Application Publication
(10) Pub. No.: US 2022/0246707 A1
(43) Pub. Date: Aug. 4, 2022

(54) ORGANIC LIGHT-EMITTING ELEMENT AND ORGANIC LIGHT-EMITTING DISPLAY DEVICE INCLUDING THE SAME

(71) Applicant: SAMSUNG ELECTRONICS CO., LTD., Suwon-si (KR)

(72) Inventors: Ajeong CHOI, Suwon-si (KR); Hyun KOO, Seongnam-si (KR); Wonjae JOO, Seongnam-si (KR)

(73) Assignee: SAMSUNG ELECTRONICS CO., LTD., Suwon-si (KR)

(21) Appl. No.: 17/405,728

(22) Filed: Aug. 18, 2021

(30) Foreign Application Priority Data
Jan. 29, 2021 (KR) 10-2021-0013470

(51) Int. Cl. H01L 27/32; H01L 51/52

(52) U.S. Cl. CPC H01L 27/3265; H01L 27/3258; H01L 2227/323; H01L 27/3211; H01L 51/5234; H01L 51/5271

(57) ABSTRACT

Provided is an organic light-emitting element including a substrate, a thin film transistor provided on the substrate, a first insulating layer provided on the substrate and the thin film transistor, a reflective layer provided on the first insulating layer, the reflective layer being electrically connected to a first portion of the thin film transistor, a second insulating layer provided on the first insulating layer and the reflective layer, an anode provided on the second insulating layer, the anode being electrically connected to a second portion of the thin film transistor that is different from the first portion of the thin film transistor, an emission layer provided on the anode, and a cathode provided on the emission layer, wherein the reflective layer and the anode overlap each other with the second insulating layer interposed therebetween to form a storage capacitor.

### CROSS-REFERENCE TO RELATED APPLICATION

This application is based on and claims priority under 35 U.S.C. § 119 to Korean Patent Application No. 10-2021-0013470, filed on Jan. 29, 2021, in the Korean Intellectual Property Office, the disclosure of which is incorporated by reference herein in its entirety.

### BACKGROUND

### 1. Field

Example embodiments of the present disclosure relate to organic light-emitting elements and organic light-emitting display devices including the same, and more particularly, to structures of storage capacitors applicable to organic light-emitting elements.

### 2. Description of Related Art

An organic light-emitting diode (OLED) is an organic light-emitting element in which holes supplied from an anode are combined with electrons supplied from a cathode in an organic emission layer to emit light. A display device including such an organic light-emitting element may exhibit excellent display characteristics such as a wide viewing angle, fast response speed, small thickness, low manufacturing cost, and high contrast.

In the case of an organic light-emitting element, light of a desired color may be emitted by selecting an appropriate material as the material of an organic emission layer. According to this principle, it is possible to implement a color display device using an organic light-emitting element. For example, an organic emission layer including blue pixels may include an organic material generating blue light, an organic emission layer including green pixels may include an organic material generating green light, and an organic emission layer including red pixels may include an organic material generating red light. Alternatively, an RGB OLED method in which a plurality of organic materials respectively generating blue light, green light, and red light are arranged in one organic emission layer may be used, or a WOLED method in which a white organic electroluminescent diode (W-OLED) is implemented by arranging pairs of two or more kinds of organic materials that are complementary to each other may also be used.

An organic light-emitting element may further include a storage capacitor for maintaining the amount of charges supplied to an organic emission layer at a certain level and reducing a kick back phenomenon. Such a storage capacitor may be formed on a driving circuit board provided with a switching thin film transistor and a driving thin film transistor for driving an organic light-emitting element. In this case, a separate space for forming the storage capacitor on the driving circuit board should be secured. However, in the case of manufacturing a high-resolution display device having a small pixel size, the design area of the driving circuit board is small, and thus, it may be difficult to secure a separate space for forming the storage capacitor on the driving circuit board.

### SUMMARY

One or more example embodiments provide organic light-emitting elements where a space in which a storage capacitor is provided is minimized, and organic light-emitting display devices including the same.

Additional aspects will be set forth in part in the description which follows and, in part, will be apparent from the description, or may be learned by practice of example embodiments.

According to an aspect of an example embodiment, there is provided an organic light-emitting element including a substrate, a thin film transistor provided on the substrate, a first insulating layer provided on the substrate and the thin film transistor, a reflective layer provided on the first insulating layer, the reflective layer being electrically connected to a first portion of the thin film transistor, a second insulating layer provided on the first insulating layer and the reflective layer, an anode provided on the second insulating layer, the anode being electrically connected to a second portion of the thin film transistor that is different from the first portion of the thin film transistor, an emission layer provided on the anode, and a cathode provided on the emission layer, wherein the reflective layer and the anode overlap each other with the second insulating layer interposed therebetween to form a storage capacitor.

The first insulating layer may include a first hole exposing the first portion of the thin film transistor and a second hole exposing the second portion of the thin film transistor.

The reflective layer may be electrically connected to the first portion of the thin film transistor through the first hole.

The anode may be electrically connected to the second portion of the thin film transistor through the second hole.

The second insulating layer may include a third hole connected to the second hole that exposes the second portion of the thin film transistor, and the anode may be electrically connected to the second portion of the thin film transistor through the second hole and the third hole.

The thin film transistor may include a first thin film transistor including a first gate electrode, a first source electrode, a first drain electrode, and a first channel, and a second thin film transistor including a second gate electrode, a second source electrode, a second drain electrode, and a second channel, wherein the first portion of the thin film transistor is the first gate electrode of the first thin film transistor, and the second portion of the thin film transistor is the first drain electrode of the first thin film transistor.

The first gate electrode of the first thin film transistor may be electrically connected to the second drain electrode of the second thin film transistor.

The thin film transistor may overlap the reflective layer with the first insulating layer interposed therebetween.

The thin film transistor may include a bottom gate type thin film transistor.

The thin film transistor may include a top gate type thin film transistor.

The organic light-emitting element may further include a pixel defining layer provided between the anode and the cathode, the pixel defining layer being provided adjacent to surround the emission layer.

The reflective layer may form a microcavity with the cathode, and an optical length of the microcavity is an integer multiple of a half-wavelength of light emitted from the emission layer.

A plurality of nanostructures may be formed on the reflective layer.

The anode may be a transparent electrode, and the cathode may be a semi-transmissive electrode configured to reflect a part of light and transmit another part of light.

The cathode may include a reflective metal, and a thickness of the cathode may be in a range from 10 nm to 20 nm.

The reflective layer may include gold, silver, or an alloy containing gold or silver.

The emission layer may be configured to emit white light.

A hole injection layer provided on the anode and a hole transport layer provided on the hole injection layer may be sequentially provided between the anode and the emission layer, and an electron transport layer provided on the emission layer and an electron injection layer provided on the electron transport layer may be sequentially provided between the emission layer and the cathode.

According to another aspect of an example embodiment, there is provided an organic light-emitting display device including a plurality of pixels, wherein each of the plurality of pixels includes a substrate, a thin film transistor provided on the substrate, a first insulating layer provided on the substrate and the thin film transistor, a reflective layer provided on the first insulating layer, the reflective layer being electrically connected to a first portion of the thin film transistor, a second insulating layer provided on the first insulating layer and the reflective layer, an anode provided on the second insulating layer, the anode being electrically connected to a second portion different of the thin film transistor that is different from the first portion of the thin film transistor, an emission layer provided on the anode, and a cathode provided on the emission layer, wherein the reflective layer and the anode overlap each other with the second insulating layer interposed therebetween to form a storage capacitor.

An optical length between the reflective layer and the cathode of each pixel of the plurality of pixels may be different from each other.

### BRIEF DESCRIPTION OF THE DRAWINGS

The above and/or other aspects, features, and advantages of example embodiments will be more apparent from the following description taken in conjunction with the accompanying drawings, in which:

FIG. 1 is a side cross-sectional view illustrating an example structure of an organic light-emitting element according to an example embodiment;

FIG. 2 is a plan view illustrating an example structure of the organic light-emitting element of FIG. 1;

FIG. 3 illustrates an example structure of a light-emitting structure included in the organic light-emitting element of FIG. 1;

FIG. 4 illustrates an example structure of an emission layer of FIG. 1;

FIG. 5 is a side cross-sectional view illustrating an example structure of a reflective layer included in the organic light-emitting element of FIG. 1;

FIG. 6 is a side cross-sectional view schematically illustrating an example structure of an organic light-emitting element according to a related embodiment;

FIG. 7 is a side cross-sectional view schematically illustrating an example configuration of an organic light-emitting element according to another example embodiment;

FIG. 8 is a view for explaining a method of manufacturing an organic light-emitting element according to an example embodiment;

FIG. 9 is a view for explaining a method of manufacturing an organic light-emitting element according to an example embodiment;

FIG. 10 is a view for explaining a method of manufacturing an organic light-emitting element according to an example embodiment;

FIG. 11 is a view for explaining a method of manufacturing an organic light-emitting element according to an example embodiment;

FIG. 12 is a view for explaining a method of manufacturing an organic light-emitting element according to an example embodiment;

FIG. 13 is a view for explaining a method of manufacturing an organic light-emitting element according to an example embodiment;

FIG. 14 is a view for explaining a method of manufacturing an organic light-emitting element according to an example embodiment;

FIG. 15 is a view for explaining a method of manufacturing an organic light-emitting element according to an example embodiment;

FIG. 16 is a view for explaining a method of manufacturing an organic light-emitting element according to an example embodiment;

FIG. 17 is a view for explaining a method of manufacturing an organic light-emitting element according to an example embodiment; and

FIG. 18 is a plan view schematically illustrating an example configuration of an organic light-emitting display device according to an example embodiment.

### DETAILED DESCRIPTION

Reference will now be made in detail to example embodiments of which are illustrated in the accompanying drawings, wherein like reference numerals refer to like elements throughout. In this regard, the example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In the drawings, the size or thickness of each component may be exaggerated for clarity and convenience.

Hereinafter, what is described as “on” or “over” may include not only that which is directly above in contact, but also that which is above in a non-contact manner. As used herein, the singular forms “a”, “an” and “the” are intended to include the plural forms as well, unless the context clearly indicates otherwise. When a part is said to “include” a component, this means that other components may be further included instead of excluding other components, unless otherwise stated.

The use of the term “above-described” and similar indication terms may correspond to both singular and plural. The use of all examples or illustrative terms is merely for describing technical ideas in detail, and the scope of the present disclosure is not limited by the examples or illustrative terms unless limited by the claims.

Although the terms “first”, “second”, etc., may be used herein to describe various elements, components, regions, and/or layers, these elements, components, regions, and/or layers should not be limited by these terms. These terms are used only to distinguish one component from another, not for purposes of limitation.

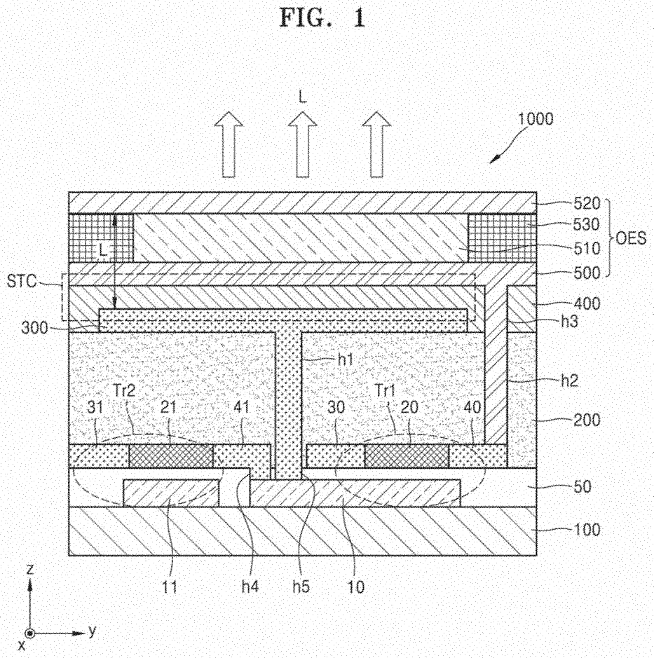

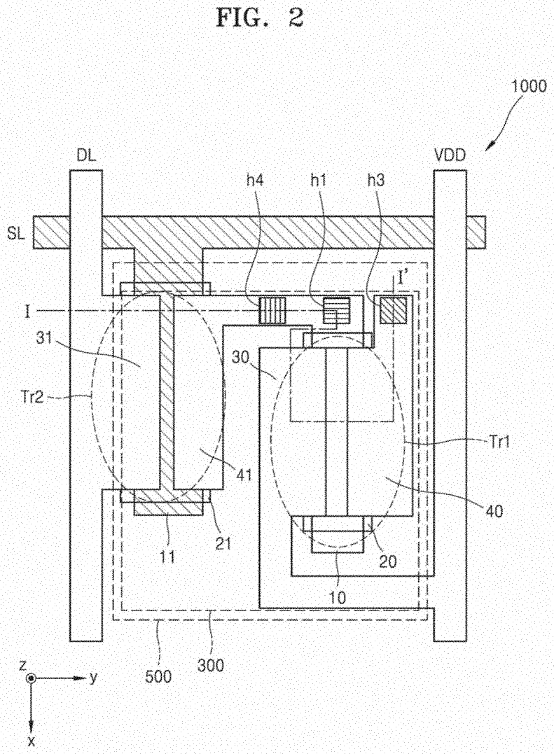

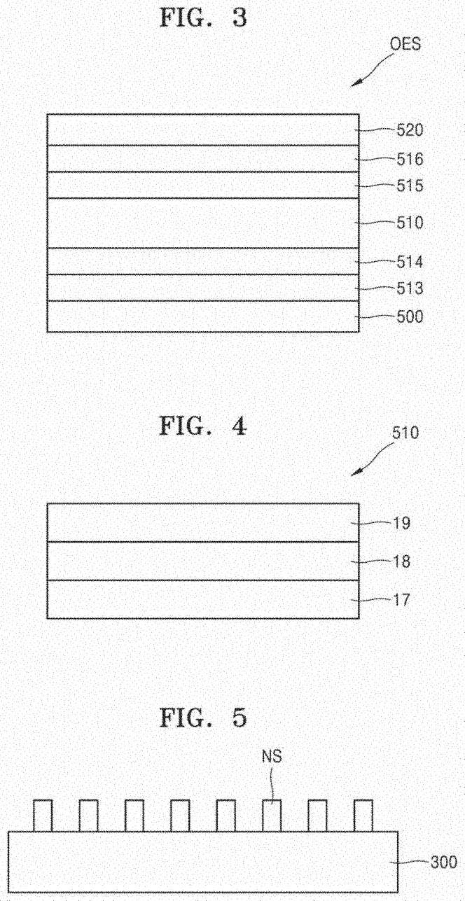

FIG. 1 is a side cross-sectional view illustrating an example structure of an organic light-emitting element 1000 according to an example embodiment. FIG. 2 is a plan view illustrating an example structure of the organic light-emitting element 1000 of FIG. 1. FIG. 3 schematically illustrates an example structure of a light-emitting structure OES included in the organic light-emitting element 1000 of FIG. 1. FIG. 4 schematically illustrates an example structure of the emission layer 510 of FIG. 1.

The structure shown in FIG. 1 has a slight difference in spacing, width, etc. between components as compared with a cross section taken along the line I-I′ of FIG. 2, but may be substantially the same. For convenience of explanation, in FIG. 2, a second insulating layer 400, an emission layer 510, a cathode 520, and a pixel defining layer 530 of FIG. 1 are omitted.

Referring to FIG. 1, the organic light-emitting element 1000 may include a substrate 100, thin film transistors Tr1 and Tr2 provided on the substrate 100, a first insulating layer 200 provided on the substrate 100 to cover the thin film transistors Tr1 and Tr2, a reflective layer 300 provided on the first insulating layer 200 and formed to be electrically connected to a first portion of each of the thin film transistors Tr1 and Tr2, a second insulating layer 400 provided on the first insulating layer 200 to cover the reflective layer 300, an anode 500 provided on the second insulating layer 400 and formed to be electrically connected to a second portion different from the first portion of each of the thin film transistors Tr1 and Tr2, an emission layer 510 provided on the anode 500, and a cathode 520 of the emission layer 510. The organic light-emitting element 1000 may further include a pixel defining layer 530 provided between the anode 500 and the cathode 520 and formed to surround the emission layer 510.

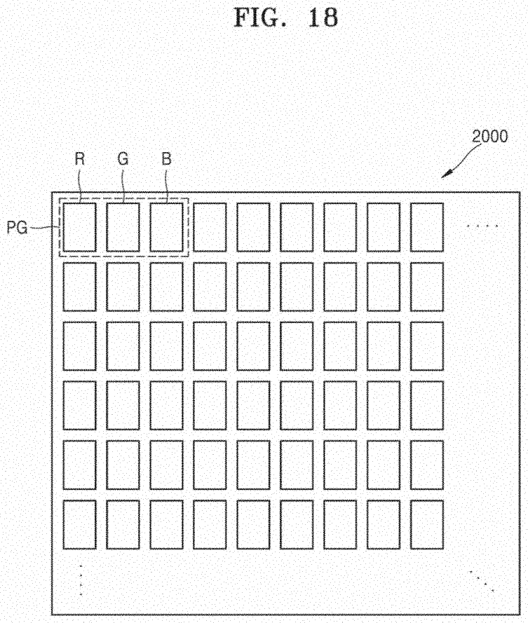

The organic light-emitting element 1000 may correspond to one of a plurality of pixels included in an organic light-emitting display device. For example, the organic light-emitting display device may include a plurality of organic light-emitting elements 1000, and each of the plurality of organic light-emitting elements 1000 may operate as one pixel of the organic light-emitting display device. An example structure of the organic light-emitting display device will be described later with reference to FIG. 18.

The anode 500, the emission layer 510, and the cathode 520 may form a light-emitting structure OES. The light-emitting structure OES may be an organic light-emitting diode (OLED). For example, the light-emitting structure OES may be a white organic light-emitting structure that emits white light. Referring to FIG. 3, the light-emitting structure OES may include a hole injection layer 513 provided on the anode 500, a hole transport layer 514 provided on the hole injection layer 513, an emission layer 510 provided on the hole transport layer 514, an electron transport layer 515 provided on the emission layer 510, and an electron injection layer 516 provided on the electron transport layer 515. In this case, the emission layer 510 may be a white organic emission layer that emits white light.

Further, the light-emitting structure OES may include various additional layers as needed. For example, the light-emitting structure OES may further include an electron blocking layer provided between the hole transport layer 514 and the emission layer 510. Further, the light-emitting structure OES may further include a hole blocking layer provided between the emission layer 510 and the electron transport layer 515. In this structure, holes provided through the hole injection layer 513 and the hole transport layer 514 are combined with electrons provided through the electron injection layer 516 and the electron transport layer 515 to emit light.

Further, referring to FIG. 4, the emission layer 510 may include a first organic emission layer 17 emitting light of a first wavelength, a second organic emission layer 18 provided on the first organic emission layer 17 and emitting light of a second wavelength, and a third organic emission layer 19 provided on the second organic emission layer 18 and emitting light of a third wavelength. The wavelengths of light generated from the first, second, and third organic emission layers 17, 18, and 19 may determined by the energy band gaps of light-emitting materials of the first, second, and third organic emission layers 17, 18, and19, respectively. For example, the first organic emission layer 17 may include a red light-emitting material. Further, the second organic emission layer 18 may include a green light-emitting material. Moreover, the third organic emission layer 19 may include a blue light-emitting material. Accordingly, red light, green light, and blue light may be generated from the first, second, and third organic emission layers 17, 18, and 19, respectively, and these three types of lights may be mixed to form white light. The emission layer 510 may include various additional layers as necessary. For example, at least one of an additional electron transport layer and an additional hole transport layer may be further provided between the first organic emission layer 17 and the second organic emission layer 18. Further, at least one of an additional electron transport layer and an additional hole transport layer may be further provided between the second organic emission layer 18 and the third organic emission layer 19.

The light-emitting structure OES may be provided on a driving circuit board including a substrate 100 and thin film transistors Tr1 and Tr2 to be described later. The light-emitting structure OES may generate light according to a driving signal from the driving circuit board. The connection between the light-emitting structure OES and the driving circuit board will be described later.

The substrate 100 may include a semiconductor substrate or an insulating substrate. For example, as the substrate 100, various semiconductor substrates including silicon, silicon carbide, germanium, silicon-germanium, and III-V semiconductor materials may be applied. An insulating substrate such as a sapphire substrate may be used as the substrate 100. However, this is illustrative, and the material of the substrate 100 is not limited thereto, and may be variously changed.

Referring to FIG. 1, thin film transistors Tr1 and Tr2 may be provided on the substrate 100. For example, a first thin film transistor Tr1 and a second thin film transistor Tr2 may be provided on the substrate 100. The first thin film transistor Tr1 may be a driving thin film transistor that transmits a driving signal to the light-emitting structure OES. The second thin film transistor Tr2 may be a switching thin film transistor that controls the driving of the first thin film transistor Tr1. A structure including the substrate 100 and the thin film transistors Tr1 and Tr2 may be referred to as a driving circuit board.

The first thin film transistor Tr1 may include a first gate electrode 10, a first channel 20, a first source electrode 30, and a first drain electrode 40. The first gate electrode 10 and the first channel 20 may be formed to face each other and be spaced apart from each other with a gate insulating layer 50 interposed therebetween. The first source electrode 30 and the first drain electrode 40 may be in contact with both ends of the first channel 20, respectively and provided adjacent to the first channel 20.

The second thin film transistor Tr2 may include a second gate electrode 11, a second channel 21, a second source electrode 31, and a second drain electrode 41. The second gate electrode 11 and the second channel 21 may be formed to face each other and be spaced apart from each other with the gate insulating layer 50 interposed therebetween. The second source electrode 31 and the second drain electrode 41 may be in contact with both ends of the second channel 21, respectively and provided adjacent to the second channel 21.

As shown in FIG. 1, the first and second gate electrodes 10 and 11 may be provided on the substrate 100, and the gate insulating layer 50 formed to cover the first and second gate electrodes 10 and 11 may be provided on the substrate 100. The first and second channels 20 and 21, the first and second source electrodes 30 and 31, and the first and second drain electrodes 40 and 41 may be provided on the gate insulating layer 50. As such, the first and second thin film transistors Tr1 and Tr2 may include bottom gate type thin film transistors in which the first and second gate electrodes 10 and 11 are provided under the first and second channels 20 and 21.

The first thin film transistor Tr1 and the second thin film transistor Tr2 may be electrically connected to each other. The first gate electrode 10 of the first thin film transistor Tr1 and the second drain electrode 41 of the second thin film transistor Tr2 may be electrically connected to each other. For example, the second drain electrode 41 may be formed to be in contact with the first gate electrode 10 through a first gate hole h4 formed in the gate insulating layer 50 to expose a part of the first gate electrode 10.

Referring to FIG. 2, the second transistor Tr2 may be provided in a region where a scan line SL and a data line DL cross each other. The second thin film transistor Tr2 functioning as a switching thin film transistor may perform a function of selecting a pixel. The second thin film transistor Tr2 may include a second gate electrode 11 branched from the scan line SL, a second channel 21 provided on the second gate electrode 11, a second source electrode 31 branched from the data line DL, and a second drain electrode 41.

The first thin film transistor Tr1 functioning as a driving thin film transistor may serve to drive the light-emitting structure OES of the pixel selected by the second thin film transistor Tr2. The first thin film transistor Tr1 may include a first gate electrode 10 connected to the second drain electrode 41 of the second thin film transistor Tr2, a first channel 20 provided on the first gate electrode 10, a first source electrode 30 connected to a driving current line VDD, and a first drain electrode 40.

The second drain electrode 41 of the second thin film transistor Tr2 and the first gate electrode 10 of the first thin film transistor Tr1 may be connected by the first gate hole h4. For example, the second drain electrode 41 may extend to fill the inside of the first gate hole h4 and contact the first gate electrode 10.

A first insulating layer 200 provided to cover the thin film transistors Tr1 and Tr2 may be formed on the substrate 100. For example, the first insulating layer 200 may be formed to cover the first and second channels 20 and 21, the first and second source electrodes 30 and 31, the first and second drain electrodes 40 and 41, and the gate insulating layer 50.

The first insulating layer 200 may include a dielectric material. For example, the first insulating layer 200 may include any one of aluminum oxide (A1203), silicon oxide (SiOx), AlOx, silicon oxynitride (SiON), and silicon nitride (SiN), or a combination thereof. For example, the first insulating layer 200 may include any one of SiO and AlO. The first insulating layer 200 may further include a dopant such as silicon (Si), aluminum (Al), zirconium (Zr), yttrium (Y), lanthanum (La), gadolium (Gd), strontium (Sr), hafnium (Hf), or cerium (Ce) in addition to any one of Al₂O₃, SiOx, AlOx, SiON, and SiN. However, embodiments are not limited thereto, and the type of dopant may include materials other than the aforementioned materials. Moreover, the first insulating layer 200 may include other dielectric materials having insulating properties in addition to the aforementioned materials.

The first insulating layer 200 may include a first hole h1 exposing a first portion of each of the thin film transistors Tr1 and Tr2 and a second hole h2 exposing a second portion of each of the thin film transistors Tr1 and Tr2. Here, the first portion may be the first gate electrode 10 of the first thin film transistor Tr1. In this case, the first hole h1 is connected to the second gate hole h5 formed in the gate insulating layer 50 to expose a part of the first gate electrode 10 of the first thin film transistor Tr1. Further, the second portion may be the first drain electrode 40 of the first thin film transistor Tr1. In this case, the second hole h2 may expose a part of the first drain electrode 40 of the first thin film transistor Tr1.

The reflective layer 300 may be provided on the first insulating layer 200. The reflective layer 300 may include a metal. For example, the reflective layer 300 may be made of gold (Au), silver (Ag), or an alloy containing gold or silver. However, embodiments are not limited thereto, and the reflective layer 300 may include a metal other than silver or gold.

The reflective layer 300 may form a microcavity L together with the cathode 520. For example, the reflective layer 300 and the cathode 520 may form a microcavity L having any optical length. The optical length of the microcavity L may be an integer multiple of a half wavelength (λ/2) of light emitted from the emission layer 510. For example, when an integer multiple of the half wavelength (λ/2) of some of the white light emitted from the emission layer 510 is the same as the optical length of the microcavity L, the light of the corresponding wavelength may resonate while reciprocating between the microcavities L formed by the reflective layer 300 and the cathode 520. The wavelength (λ) of light that resonates between the microcavities L may be a resonance wavelength. In this case, the light having a resonance wavelength may resonate between the reflective layer 300 and the cathode 520, amplified, and then emitted to the outside through the cathode 520. For example, the light emitted by the emission layer 510, resonating in the microcavity L and amplified may be emitted to the outside of the organic light-emitting element 1000 through the upper portion of the cathode 520. In this case, the anode 500 may be a transparent electrode, and the cathode 520 may be a semi-transmissive electrode that reflects a part of light and transmits a part of light. Accordingly, the light generated from the emission layer 510 may pass through the anode 500 and be reflected by the reflective layer 300, and may be reflected again by the cathode 520. In this way, the light may travel reciprocally between the reflective layer 300 and the cathode 520. For example, the cathode 520 may be made of a reflective metal, and the thickness of the cathode 520 may be 10 nm to 20 nm.

Similarly, even if white light, not light of a specific wavelength, is emitted from the emission layer 510, light of a specific wavelength may be extracted by the microcavity L formed by the reflective layer 300 and the cathode 520, and be emitted to the outside of the organic light-emitting element 1000. In this case, according to the design of the optical length of the microcavity L, a specific wavelength of light extracted from white light emitted by the emission layer 510 may be determined.

The reflective layer 300 may be formed to be electrically connected to the first gate electrode 10 of the first thin film transistor Tr1 through the first hole h1. For example, a part of the first gate electrode 10 of the first thin film transistor Tr1 may be exposed to the outside by the first hole h1 and the second gate hole h5. The reflective layer 300 may be formed to contact a part of the first gate electrode 10 through the first hole h1 and the second gate hole h5. For example, a part of the reflective layer 300 may be formed to be extended to fill the inside of the first hole h1 and the second gate hole h5.

Further, as shown in FIGS. 1 and 2, the thin film transistors Tr1 and Tr2 may be formed to overlap the reflective layer 300 with the first insulating layer 200 interposed therebetween. For example, the reflective layer 300 may be provided in a region overlapping a region in which the first and second thin film transistors Tr1 and Tr2 are formed. Accordingly, in a plan view, the organic light-emitting element 1000 on a plane perpendicular to the vertical direction (z-axis direction), the reflective layer 300 may be seen to overlap the first and second thin film transistors Tr1 and Tr2.

A second insulating layer 400 provided to cover the reflective layer 300 may be formed on the first insulating layer 200. The second insulating layer 400 may include a dielectric material. For example, the second insulating layer 400 may include any one of Al₂O₃, SiOx, AlOx, SiON, and SiN, or a combination thereof. For example, the second insulating layer 400 may include any one of SiO and A10. The second insulating layer 400 may further include a dopant such as Si, Al, Zr, Y, La, Gd, Sr, Hf, or Ce in addition to any one of Al₂O₃, SiOx, AlOx, SiON, and SiN. However, embodiments are not limited thereto, and the type of dopant may include materials other than the aforementioned materials. Moreover, the second insulating layer 400 may include other dielectric materials having insulating properties in addition to the aforementioned materials.

The second insulating layer 400 may include a third hole h3 connected to the second hole h2 of the first insulating layer 200 to expose the second portion of each of the thin film transistors Tr1 and Tr2. Here, the second portion may be the first drain electrode 40 of the first thin film transistor Tr1. In this case, the third hole h3 may be connected to the second hole h2 of the first insulating layer 200 to expose a part of the first drain electrode 40 of the first thin film transistor Tr1.

Hereinafter, a configuration in which the light-emitting structure OES that is connected to the driving circuit board including the substrate 100 and the first and second thin film transistors Tr1 and Tr2 will be described.

The light-emitting structure OES may be provided on the second insulating layer 400. For example, the anode 500, the emission layer 510, and the cathode 520 may be sequentially stacked on the second insulating layer 400. As shown in FIGS. 1 and 2, the light-emitting structure OES may be provided in a region overlapping the region in which the reflective layer 300 is formed. Accordingly, in a plan view, the organic light-emitting element 1000 on a plane perpendicular to the vertical direction (z-axis direction), the light-emitting structure OES may be seen to overlap the reflective layer 300.

The width of the emission layer 510 in a direction (x-axis direction or y-axis direction) perpendicular to the stacking direction may be narrower than the width of each of the anode 500 and the cathode 520 in a direction (x-axis direction or y-axis direction) perpendicular to the stacking direction. In this case, the organic light-emitting element 1000 may further include a pixel defining layer 530 formed between the anode 500 and the cathode 520 to surround the emission layer 510.

The anode 500 provided on the second insulating layer 400 may be formed to be electrically connected to the second portion of each of the thin film transistors Tr1 and Tr2 through the second hole h2 and the third hole h3. Here, the second portion may be the first drain electrode 40 of the first thin film transistor Tr1. In this case, the anode 500 may be formed to contact a part of the first drain electrode 40 through the second hole h2 and the third hole h3 formed to be connected to each other to expose a part of the first drain electrode 40 of the first thin film transistor Tr1. For example, a part of the anode 500 may be formed to be extended to fill the inside of the second hole h2 and the third hole h3.

As described above, the reflective layer 300 may formed to be electrically connected to the first gate electrode 10 of the first thin film transistor Tr1, and the anode 500 may be formed to be electrically connected to the first drain electrode 40 of the first thin film transistor Tr1. As such, the reflective layer 300 and the anode 500 electrically connected to the first thin film transistor Tr1 may be formed to face each other and be spaced apart from each other with the second insulating layer 400 therebetween. Accordingly, the reflective layer 300 and the anode 500 may overlap each other with the second insulating layer 400 interposed therebetween to form a storage capacitor STC. Due to the storage capacitor STC formed by the reflective layer 300 and the anode 500, the amount of charge supplied to the emission layer 510 may be maintained at a certain level, and a kick back phenomenon may be reduced. Further, the storage capacitor STC formed by the reflective layer 300 and the anode 500 may be formed in a region overlapping the first and second thin film transistors Tr1 and Tr2 in a vertical direction (z-axis direction). Accordingly, it may not be necessary to provide a separate space for providing the storage capacitor STC in a region spaced from the first and second thin film transistors Tr1 and Tr2 in the horizontal direction (x-axis and y-axis directions).

FIG. 5 is a side cross-sectional view schematically illustrating an example structure of a reflective layer 300 included in the organic light-emitting element 1000 of FIG. 1.

Referring to FIG. 5, a plurality of nanostructures NS may be provided on the upper surface of the reflective layer 300. Each of the plurality of nanostructures NS may have a cylindrical shape. However, embodiments are not limited thereto, and the plurality of nanostructures NS may have various types of pillar shapes such as a triangular pillar and a square pillar.

The size of each of the plurality of nanostructures NS may be smaller than the wavelength of light generated from the light-emitting structure OES. The plurality of nanostructures NS may be spaced apart from each other by a predetermined distance on the upper surface of the reflective layer 300 in the horizontal direction, and may be periodically arranged. For example, the arrangement period of the plurality of nanostructures NS may be 100 nm to 150 nm. However, the embodiments are not limited thereto, and the plurality of nanostructures NS may be arranged irregularly. The height of each of the plurality of nanostructures NS may be shorter than the arrangement period of the plurality of nanostructures NS. For example, the arrangement period of the plurality of nanostructures NS may be 100 nm or more, and the height of each of the plurality of nanostructures NS may be 10 nm to 100 nm. The diameter of each of the plurality of nanostructures NS may be equal to or smaller than the distance between the plurality of nanostructures NS. For example, the arrangement period of the plurality of nanostructures NS may be 100 nm or more, and the diameter of each of the plurality of nanostructures NS may be 100 nm.

Depending on the shape of the plurality of nanostructures NS, resonation for light other than the light having a resonance wavelength for the microcavity L formed by the reflective layer 300 and the cathode 520 may be suppressed. For example, some light not having a resonance wavelength for the microcavity L may also resonate inside the microcavity L. In this case, the color purity of the organic light-emitting element 1000 may be deteriorated. The plurality of nanostructures NS absorbs light not having a resonance wavelength for the micro-cavities L, thereby increasing extraction efficiency of light having a resonant wavelength for the microcavities L. Thus, the color purity of the organic light-emitting element 1000 may be improved.

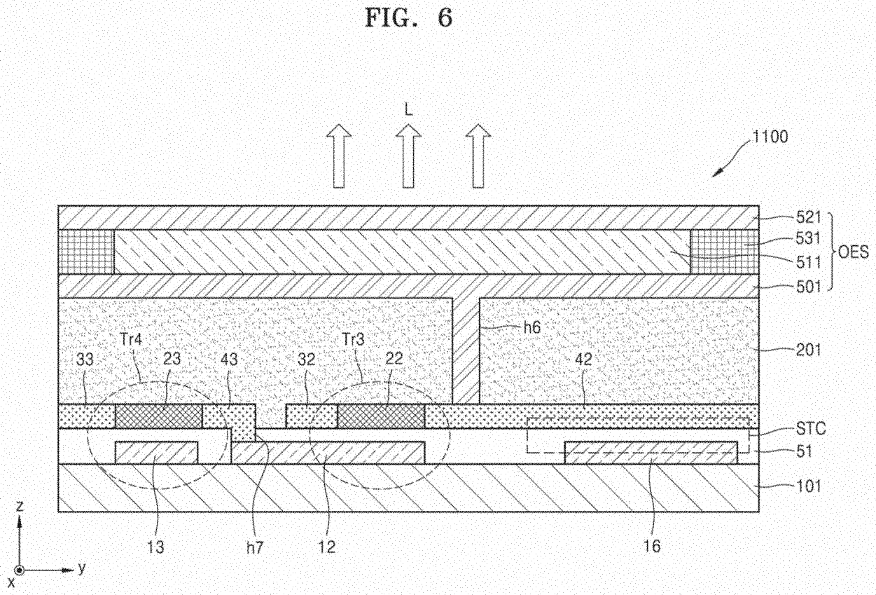

FIG. 6 is a side cross-sectional view illustrating an example structure of an organic light-emitting element 1100 according to a related embodiment.

Referring to FIG. 6, the organic light-emitting element 1100 according to a related embodiment may include a substrate 101, thin film transistors Tr3 and Tr4 provided on the substrate 101, a first insulating layer 201 provided on the substrate 101 to cover the thin film transistors Tr3 and Tr4, an anode 501 provided on the first insulating layer 201 and formed to be electrically connected to a part of each of the thin film transistors Tr3 and Tr4, an emission layer 511 provided on the anode 501, and a cathode 521of the emission layer 511. The organic light-emitting element 1100 may further include a pixel defining layer 531 provided between the anode 501 and the cathode 521 and be formed to surround the emission layer 511.

The anode 501, the emission layer 511, and the cathode 521 may form a light-emitting structure OES. The light-emitting structure OES may be an organic light-emitting diode (OLED). For example, the light-emitting structure OES may be a white organic light-emitting structure that emits white light.

Thin film transistors Tr3 and Tr4 may be provided on the substrate 101. For example, a first thin film transistor Tr3 and a second thin film transistor Tr4 may be provided on the substrate 101. The first thin film transistor Tr3 may be a driving thin film transistor that transmits a driving signal to the light-emitting structure OES. The second thin film transistor Tr4 may be a switching thin film transistor that controls the driving of the first thin film transistor Tr3. A structure including the substrate 101 and the thin film transistors Tr3 and Tr4 may be referred to as a driving circuit board.

The first thin film transistor Tr3 may include a first gate electrode 12, a first channel 22, a first source electrode 32, and a first drain electrode 42. The first gate electrode 12 and the first channel 22 may be formed to face each other and be spaced apart from each other with a gate insulating layer 51 interposed therebetween. The first source electrode 32 and the first drain electrode 42 may be in contact with both ends of the first channel 22, respectively.

The second thin film transistor Tr4 may include a second gate electrode 13, a second channel 23, a second source electrode 33, and a second drain electrode 43. The second gate electrode 13 and the second channel 23 may be formed to face each other and be spaced apart from each other with a gate insulating layer 51 interposed therebetween. The second source electrode 33 and the second drain electrode 44 may be in contact with both ends of the second channel 23, respectively.

As shown in FIG. 6, the first and second gate electrodes 12and 13 may be provided on the substrate 101, and the gate insulating layer 51 formed to cover the first and second gate electrodes 12 and 13 may be provided on the substrate 101. The first and second channels 22 and 23, the first and second source electrodes 32 and 33, and the first and second drain electrodes 42 and 43 may be provided on the gate insulating layer 51. As such, the first and second thin film transistors Tr3 and Tr4 may include bottom gate type thin film transistors in which the first and second gate electrodes 12 and 13 are provided under the first and second channels 22 and 23.

The first thin film transistor Tr3 and the second thin film transistor Tr4 may be electrically connected to each other. For example, the second drain electrode 43 may be formed to be in contact with the first gate electrode 12 through a first gate hole h7 formed in the gate insulating layer 51 to expose a part of the first gate electrode 12.

A first insulating layer 201 provided to cover the thin film transistors Tr3 and Tr4 may be formed on the substrate 101. The first insulating layer 201 may include a first hole h6 exposing a part of each of the thin film transistors Tr3 and Tr4. For example, the first hole h6 may be formed to expose a part of the first drain electrode 42 of the first thin film transistor Tr3.

The light-emitting structure OES may be provided on the first insulating layer 201. For example, the anode 501, the emission layer 511, and the cathode 521 may be sequentially stacked on the first insulating layer 201. The anode 501 provided on the first insulating layer 201 may be electrically connected to the first drain electrode 42 of the first thin film transistor Tr3 through the first hole h6. For example, the anode 501 may be formed to contact a part of the first drain electrode 42 through the first hole h6 formed to expose a part of the first drain electrode 42 of the first thin film transistor Tr3. For example, a part of the anode 501 may be formed to be extended to fill the inside of the first hole h6.

An additional electrode 16 may be provided on the substrate 101. For example, the additional electrode 16 may be provided on the substrate 101 so as to be spaced apart from the first and second gate electrodes 12 and 13 in parallel in the horizontal direction (x-axis or y-axis direction). The additional electrode 16 may be covered by the gate insulating layer 51. The additional electrode 16 may be formed under the same process as the first and second gate electrodes 12 and 13. The first drain electrode 42 may be formed to be extended to a region corresponding to the additional electrode 16. Accordingly, a part of the additional electrode 16 and a part the first drain electrode 42 may form a storage capacitor STC with the gate insulating layer 51 therebetween. Due to this storage capacitor STC, the amount of charge supplied to the emission layer 511 may be maintained at a certain level, and a kick back phenomenon may be reduced. However, in order to form the additional electrode 16, it is necessary to provide a separate space for providing the storage e capacitor STC in a region spaced from the first and second gate electrodes 12 and 13 in the horizontal direction (x-axis or y-axis direction), and thus limitations may occur in the miniaturization of the organic light-emitting element 1100.

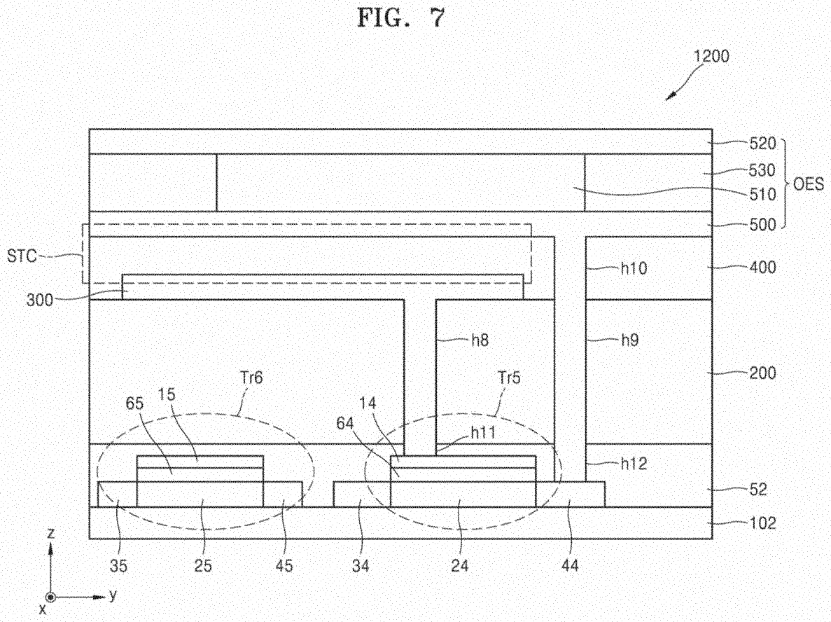

FIG. 7 is a side cross-sectional view schematically illustrating an example configuration of an organic light-emitting element 1200 according to another example embodiment. The organic light-emitting element 1200 of FIG. 7 may be substantially the same as the organic light-emitting element 1000 of FIG. 1 except that top gate type thin film transistors Tr5 and Tr6 are provided. In the description of FIG. 7, contents overlapping those of FIGS. 1 to 5 will be omitted.

Referring to FIG. 7, a first thin film transistor Tr5 and a second thin film transistor Tr6 may be provided on a substrate 102. The first thin film transistor Tr5 may include a first channel 24 provided on the substrate 102, a first source electrode 34 and a first drain electrode 44 respectively contacting both ends of the first channel 24 and provided adjacent to the first channel 24, a first gate insulating layer 64 provided on the first channel 24, and a first gate electrode 14 provided on the first gate insulating layer 64. The second thin film transistor Tr6 may include a second channel 25 provided on the substrate 102, a second source electrode 35 and a second drain electrode 45 respectively contacting both ends of the second channel 25 and provided adjacent to the second channel 25, a second gate insulating layer 65 provided on the second channel 25, and a second gate electrode 15 provided on the second gate insulating layer 65.

A transistor insulating layer 52 formed on the substrate 102 to cover the first and second thin film transistors Tr5 and Tr6 may be provided. The transistor insulating layer 52 may include a first gate hole h1 1 exposing a part of the first gate electrode 14 of the first thin film transistor Tr5 and a second gate hole h12 exposing a part of the first drain electrode 44 thereof. Although it is shown in FIG. 7 that the first and second gate insulating layers 64 and 65 are separated from the transistor insulating layer 52, embodiments are not limited thereto, and the first and second gate insulating layers 64 and 65 may be integrated with the transistor insulating layer 52.

A first insulating layer 200, a reflective layer 300, a second insulating layer 400, and a light-emitting structure OES may be sequentially stacked on the transistor insulating layer 52. An anode 500 may be provided on the upper surface of the second insulating layer 400.

The first insulating layer 200 may include a first hole h8 connected to the first gate hole h11 to expose a part of the first gate electrode 14. Further, the first insulating layer 200 may include a second hole h9 connected to the second gate hole h12 to expose a part of the first drain electrode 44.

The second insulating layer 400 may include a third hole h10 connected to the second gate hole h12 and the second hole h9 to expose a part of the first drain electrode 44.

The reflective layer 300 may be electrically connected to the first gate electrode 14 through the first hole h8 and the first gate hole h11. The anode 500 may be electrically connected to the first drain electrode 44 through the second hole h9, the third hole h10, and the second gate hole h12.

As such, the first and second thin film transistors Tr6 and Tr7 may include top gate type thin film transistors in which the first and second gate electrodes 14 and 15 are provided over the first and second channels 24 and 25.

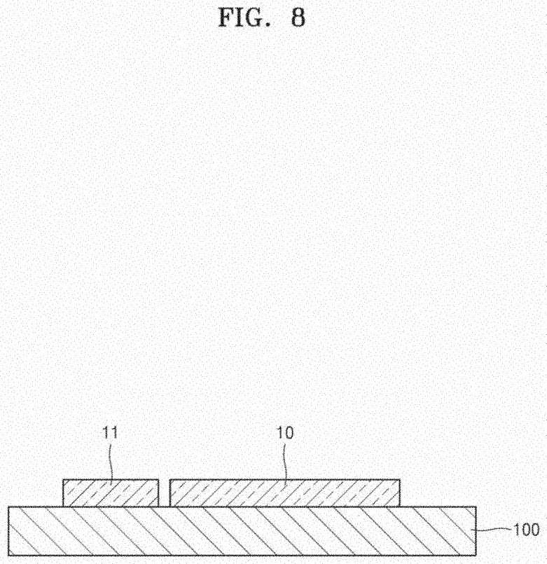

FIGS. 8 to 17 are views for explaining a method of manufacturing the organic light-emitting element 1000 according to an example embodiment.

Referring to FIG. 8, first and second gate electrodes 10 and 11 may be formed on a substrate 100. The first and second gate electrodes 10 and 11 may be formed on the upper surface of the substrate 100 to be spaced apart from each other.

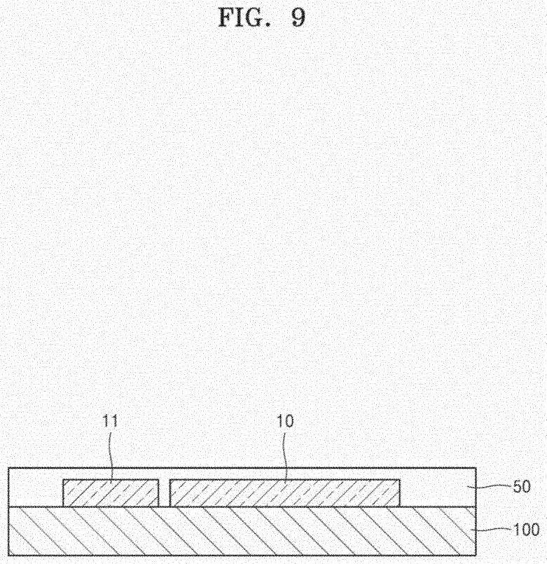

Referring to FIG. 9, a gate insulating layer 50 covering the first and second gate electrodes 10 and 11 may be formed on the substrate 100.

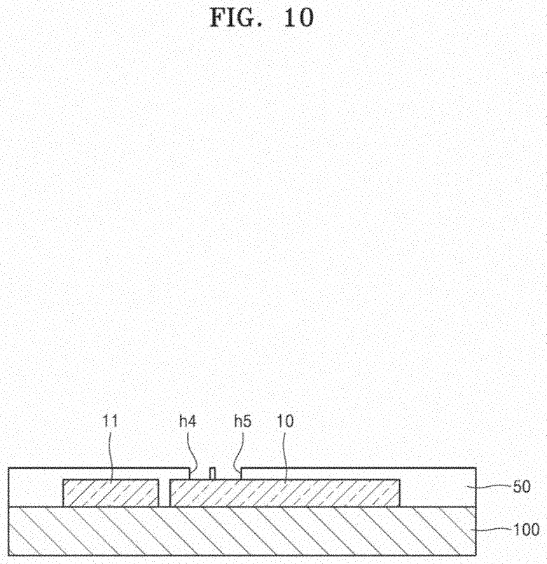

Referring to FIG. 10, a first gate hole h4 and a second gate hole h5 may be formed by patterning a part of the gate insulating layer 50 formed on the substrate 100. For example, the first gate hole h4 and the second gate hole h5 may be formed by patterning a part of the gate insulating layer 50 formed on the substrate 100. In this case, each of the first gate hole h4 and the second gate hole h5 may be formed to expose a part of the first gate electrode 10.

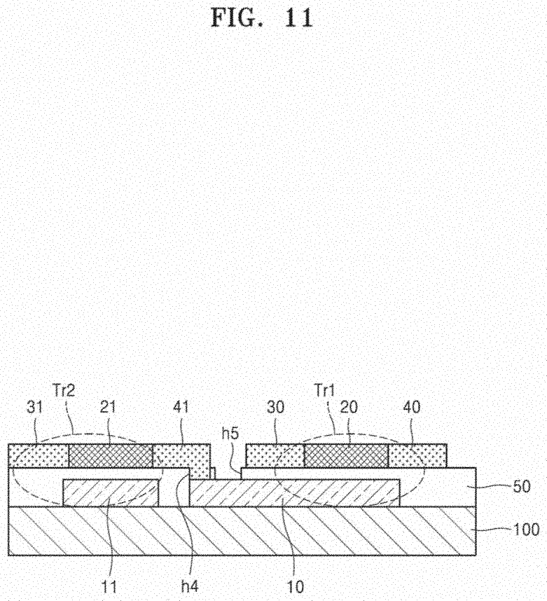

Referring to FIG. 11, first and second channels 20 and 21, first and second source electrodes 30 and 31, and first and second drain electrodes 40 and 41 may be formed on the gate insulating layer 50. Accordingly, a first thin film transistor Tr1 and a second thin film transistor Tr2 may be formed.

For example, the first channel 20 may be formed on the gate insulating layer 50 in a region corresponding to the first gate electrode 10, and the first source electrode 30 and the first drain electrode 40 may be formed in contact with both ends of the first channel 20. Further, the second channel 21 may be formed on the gate insulating layer 50 in a region corresponding to the second gate electrode 11, and the second source electrode 31 and the second drain electrode 41 may be formed in contact with both ends of the second channel 21. In this case, the second drain electrode 41 may be formed to be in contact with a part of the first gate electrode 10 through the first gate hole h4.

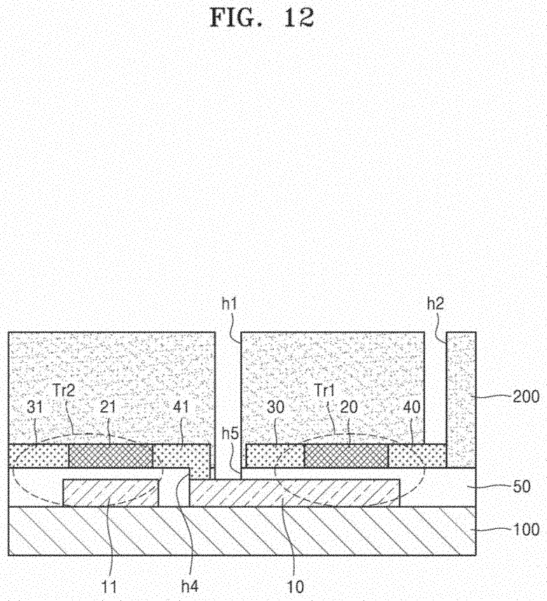

Referring to FIG. 12, a first insulating layer 200 covering the first and second thin film transistors Tr1 and Tr2 may be formed. A part of the first insulating layer 200 may be patterned to form a first hole h1 connected to the second gate hole h5 to expose a part of the first gate electrode 10. Further, another part of the first insulating layer 200 may be patterned to form a second hole h2 exposing a part of the first drain electrode 40.

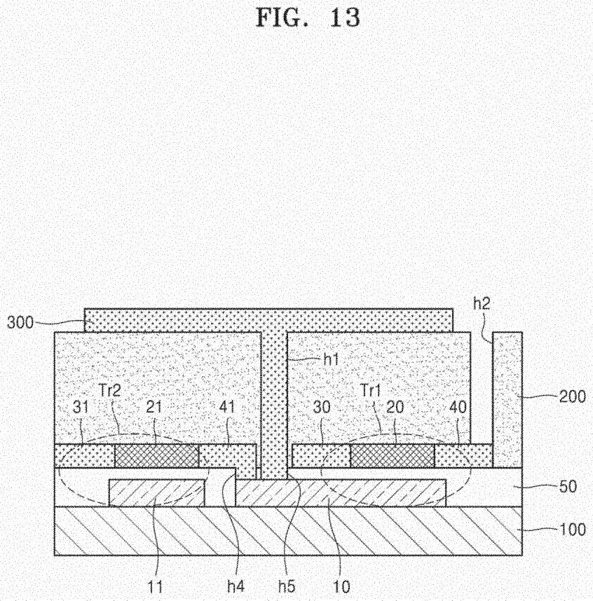

Referring to FIG. 13, a reflective layer 300 may be formed on the first insulating layer 200. In this case, the reflective layer 300 may be formed to be electrically connected to the first gate electrode 10 through the first hole h1 and the second gate hole h5. For example, the reflective layer 300 may be formed to be extended to fill the inside of the first hole h1 and the second gate hole h5, and may be formed to be in contact with the first gate electrode 10.

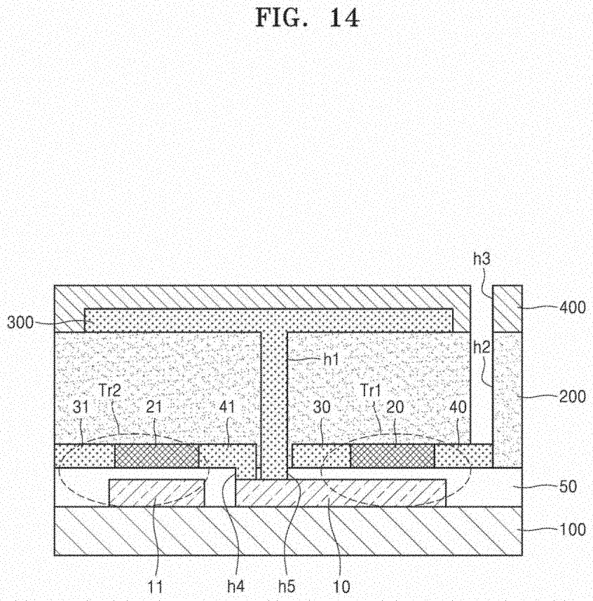

Referring to FIG. 14, a second insulating layer 400 covering the reflective layer 300 may be formed on the first insulating layer 200. In this case, a part of the second insulating layer 400 may be patterned to form a third hole h3 connected to the second hole h2 to expose a part of the first drain electrode 40.

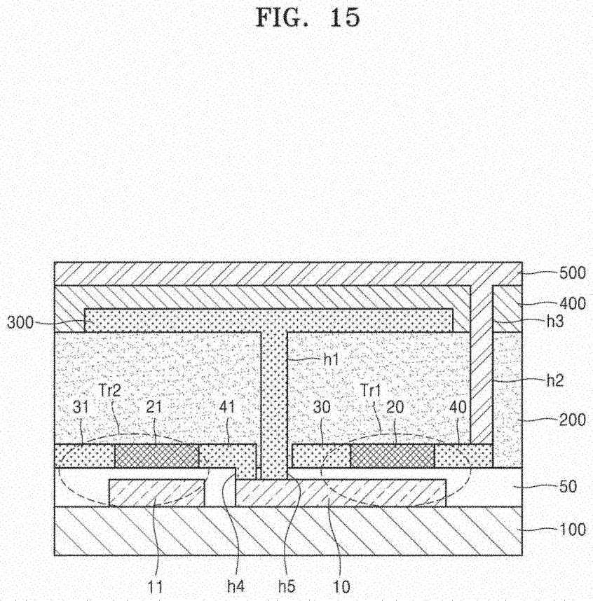

Referring to FIG. 15, an anode 500 may be formed on the second insulating layer 400. In this case, the anode 500 may be formed to be electrically connected to the first drain electrode 40 through the second hole h2 and the third hole h3. For example, the anode 500 may be formed to be extended to fill the inside of the second hole h2 and the third hole h3, and may be formed to be in contact with the first drain electrode 40.

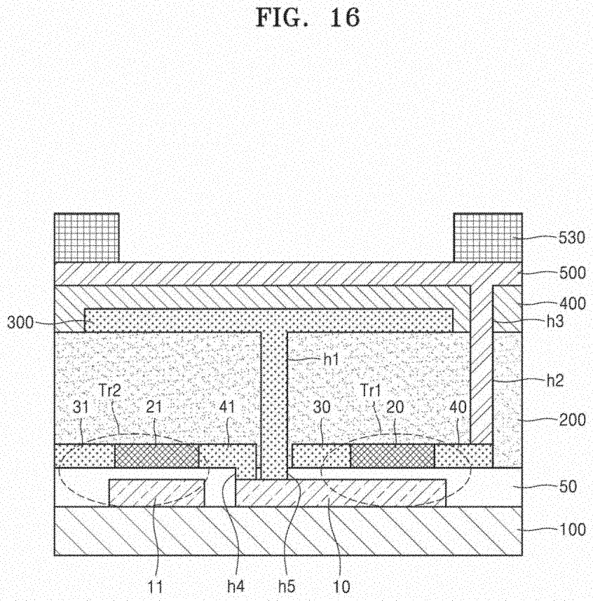

Referring to FIG. 16, a pixel defining layer 530 may be formed on the anode 500. In this case, a part of the pixel defining layer 530 may be patterned to expose a part of the anode 500.

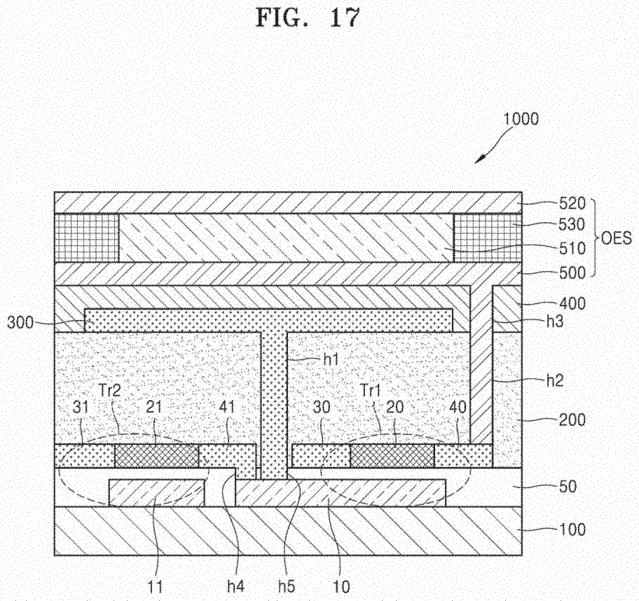

Referring to FIG. 17, an emission layer 510 may be formed in a space formed by patterning the pixel limiting layer 530, and a cathode 520 covering the emission layer 510 and the pixel defining layer 530 may be formed. Accordingly, a light-emitting structure OES may be formed.

The organic light-emitting element 1000 may be manufactured by a series of manufacturing processes described with reference to FIGS. 8 to 17. The organic light-emitting element 1000 may include a storage capacitor formed between the first and second transistors Tr1 and Tr2 and the light-emitting structure OES. This storage capacitor may be formed by the reflective layer 300 and the anode 500. Due to this storage capacitor, the amount of charges supplied to the emission layer 510 may be maintained at a certain level, and a kick back phenomenon may be reduced. Further, the storage capacitor formed by the reflective layer 300 and the anode 500 may be formed in a region overlapping the first and second thin film transistors Tr1 and Tr2 in the vertical direction. Accordingly, it may not be necessary to provide a separate space for providing the storage capacitor in a region spaced from the first and second thin film transistors Tr1 and Tr2 in the horizontal direction.

FIG. 18 is a plan view schematically illustrating an example configuration of an organic light-emitting display device 2000 according to an example embodiment.

Referring to FIG. 18, the organic light-emitting display device 2000 may include a plurality of pixels R, G, and B. For example, the organic light-emitting display device 2000 may include a plurality of pixels R, G, and B that emit light of different wavelengths. The plurality of pixels R, G, and B may include a first pixel R that emits red light, a second pixel G that emits green light, and a third pixel B that emits blue light. The first to third pixels R, G, and B may form one pixel group PG. In the organic light-emitting display device 2000, a plurality of pixel groups PG may be regularly arranged. The first pixel R, the second pixel G, and the third pixel B may include any one of the organic light-emitting elements 1000 and 1200 described with reference to FIG. 1 or 7.

The optical distance between the reflective layer 300 and the cathode 520 of each of the plurality of pixels R, G, and B may be different from each other. Accordingly, the wavelength of light resonating between the reflective layer 300 and the cathode 520 may be changed, and light of different wavelengths from each other may be emitted from each of the plurality of pixels R, G, and B.

The above-described various example embodiments are merely example, and those having ordinary knowledge in the art can understand that various modifications and equivalent other embodiments are possible therefrom. Therefore, the true technical protection scope according to various example embodiments should be defined by the technical idea of the present disclosure described in the following claims.

According to various example embodiments of the present disclosure, there may be provided organic light-emitting elements where a space in which a storage capacitor is provided is minimized, and organic light-emitting display devices including the same.

According to various example embodiments of the present disclosure, a storage capacitor may be formed between a thin film transistor and a light-emitting structure, so that it is possible to minimize a space in which the storage capacitor is provided on the organic light-emitting element.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims, and their equivalents.

What is claimed is:

1. An organic light-emitting element comprising:
a substrate;
a thin film transistor provided on the substrate;
a first insulating layer provided on the substrate and the thin film transistor;
a reflective layer provided on the first insulating layer, the reflective layer being electrically connected to a first portion of the thin film transistor;
a second insulating layer provided on the first insulating layer and the reflective layer;
an anode provided on the second insulating layer, the anode being electrically connected to a second portion of the thin film transistor that is different from the first portion of the thin film transistor;
an emission layer provided on the anode; and
a cathode provided on the emission layer,
wherein the reflective layer and the anode overlap each other with the second insulating layer interposed therebetween to form a storage capacitor.

2. The organic light-emitting element of claim 1, wherein the first insulating layer comprises a first hole exposing the first portion of the thin film transistor and a second hole exposing the second portion of the thin film transistor.

3. The organic light-emitting element of claim 2, wherein the reflective layer is electrically connected to the first portion of the thin film transistor through the first hole.

4. The organic light-emitting element of claim 2, wherein the anode is electrically connected to the second portion of the thin film transistor through the second hole.

5. The organic light-emitting element of claim 2, wherein the second insulating layer comprises a third hole connected to the second hole that exposes the second portion of the thin film transistor, and
wherein the anode is electrically connected to the second portion of the thin film transistor through the second hole and the third hole.

6. The organic light-emitting element of claim 1, wherein the thin film transistor comprises:
a first thin film transistor comprising a first gate electrode, a first source electrode, a first drain electrode, and a first channel; and
a second thin film transistor comprising a second gate electrode, a second source electrode, a second drain electrode, and a second channel, and
wherein the first portion of the thin film transistor is the first gate electrode of the first thin film transistor, and the second portion of the thin film transistor is the first drain electrode of the first thin film transistor.

7. The organic light-emitting element of claim 6, wherein the first gate electrode of the first thin film transistor is electrically connected to the second drain electrode of the second thin film transistor.

8. The organic light-emitting element of claim 1, wherein the thin film transistor overlaps the reflective layer with the first insulating layer interposed therebetween.

9. The organic light-emitting element of claim 1, wherein the thin film transistor comprises a bottom gate type thin film transistor.

10. The organic light-emitting element of claim 1, wherein the thin film transistor comprises a top gate type thin film transistor.

11. The organic light-emitting element of claim 1, further comprising a pixel defining layer provided between the anode and the cathode and adjacent to the emission layer.

12. The organic light-emitting element of claim 1, wherein the reflective layer forms a microcavity with the cathode, and an optical length of the microcavity is an integer multiple of a half-wavelength of light emitted from the emission layer.

13. The organic light-emitting element of claim 1, wherein a plurality of nanostructures provided on the reflective layer.

14. The organic light-emitting element of claim 1, wherein the anode is a transparent electrode, and the cathode is a semi-transmissive electrode configured to reflect a part of light and transmit another part of light.

15. The organic light-emitting element of claim 14, wherein the cathode comprises a reflective metal, and
wherein a thickness of the cathode is in a range from 10 nm to 20 nm.

16. The organic light-emitting element of claim 1, wherein the reflective layer comprises gold, silver, or an alloy containing gold or silver.

17. The organic light-emitting element of claim 1, wherein the emission layer is configured to emit white light.

18. The organic light-emitting element of claim 1, wherein a hole injection layer provided on the anode and a hole transport layer provided on the hole injection layer are sequentially provided between the anode and the emission layer, and
wherein an electron transport layer provided on the emission layer and an electron injection layer provided on the electron transport layer are sequentially provided between the emission layer and the cathode.

19. An organic light-emitting display device comprising:
a plurality of pixels,
wherein each of the plurality of pixels comprises:
a substrate;
a thin film transistor provided on the substrate;
a first insulating layer provided on the substrate and the thin film transistor;
a reflective layer provided on the first insulating layer, the reflective layer being electrically connected to a first portion of the thin film transistor;
a second insulating layer provided on the first insulating layer and the reflective layer;
an anode provided on the second insulating layer, the anode being electrically connected to a second portion different of the thin film transistor that is different from the first portion of the thin film transistor;
an emission layer provided on the anode; and
a cathode provided on the emission layer,
wherein the reflective layer and the anode overlap each other with the second insulating layer interposed therebetween to form a storage capacitor.

20. The organic light-emitting display device of claim 19, wherein an optical length between the reflective layer and the cathode of each pixel of the plurality of pixels is different from each other.
